(19) United States
(12) Patent Application Publication
(10) Pub. No.: US 2015/0155222 A1
(43) Pub. Date: Jun. 4, 2015

(54) SEMICONDUCTOR DIE HAVING IMPROVED THERMAL PERFORMANCE

(71) Applicant: RF Micro Devices, Inc., Greensboro, NC (US)

(72) Inventors: Jeffrey Blanton Shealy, Cornelius, NC (US); Michael Dyke LeFevre, Maricopa, AZ (US); Brian Allen Trabert, Summerfield, NC (US); Christopher Thomas Burns, Tempe, AZ (US); Michael Thomas Fresina, Greensboro, NC (US); Ramakrishna Vetury, Charlotte, NC (US)

(21) Appl. No.: 14/557,940

(22) Filed: Dec. 2, 2014

Related U.S. Application Data
(60) Provisional application No. 61/910,549, filed on Dec. 2, 2013.

(51) Int. Cl. H01L 23/48; H01L 21/306; H01L 29/20; H01L 21/768

(52) U.S. Cl. CPC H01L 23/481; H01L 21/76898; H01L 21/30604; H01L 21/30612; H01L 29/2003

(57) ABSTRACT

A semiconductor die having improved thermal performance is disclosed. The semiconductor die includes a substrate having a device layer with a plurality of vias that pass through the substrate and the device layer, wherein individual ones of the plurality of vias have an open space volume of less than around about 70,000 cubic micrometers to around about 20,000 cubic micrometers. In at least one embodiment, the substrate of the semiconductor die is made of silicon carbide (SiC) and the device layer is made of gallium nitride (GaN).

### RELATED APPLICATIONS

This application claims the benefit of U.S. provisional patent application No. 61/910,549, filed Dec. 2, 2013, the disclosure of which is incorporated herein by reference in its entirety.

### FIELD OF THE DISCLOSURE

The present disclosure is related to semiconductor manufacturing and in particular to the manufacture of semiconductor power devices.

### BACKGROUND

Semiconductor dies that include multi-finger gallium nitride (GaN)-based power devices utilize via holes through a relatively thick silicon carbide (SiC) substrate. A problem with such via holes is that relatively large air cavities are created that do not allow for efficient cooling of the GaN-based power devices. In effect, too much material from the SiC substrate is removed during fabrication of the via holes. Air filled cavities within the volumes of the via holes create an undesirable insulating effect. What is needed is a semiconducting die having improved thermal performance.

### SUMMARY

A semiconductor die having improved thermal performance is disclosed. The semiconductor die includes a substrate having a device layer with a plurality of vias that pass through the substrate and the device layer, wherein individual ones of the plurality of vias have an open space volume of less than around about 70,000 cubic micrometers to around about 20,000 cubic micrometers. In at least one embodiment, the substrate of the semiconductor die is made of silicon carbide (SiC) and the device layer is made of gallium nitride (GaN).

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure, and together with the description serve to explain the principles of the disclosure.

FIG. 1 is a depiction of a related art semiconductor die having an oval via that has a relatively large air cavity that results in poor thermal performance for the related art semiconductor die.

FIG. 2 is a diagram of an elliptical frustum and an associated equation for volume V_{E} that is usable to approximate the open space volume of the oval via depicted in FIG. 1.

FIG. 3 is a depiction of a semiconductor die having a substantially cylindrical via and a substantially square via that are both in accordance with the present disclosure.

FIG. 4 is a diagram of a cylinder and an associated equation for the volume V_{C} of the circular/cylindrical via FIG. 3.

FIG. 5 is a diagram of a box and associated equation for calculating the box-shaped volume of the substantially square via depicted in FIG. 3.

FIG. 6 is a process flow chart for manufacturing the semiconductor die of FIG. 3 in accordance with the present disclosure.

FIG. 7A is a line drawing of a topside of a gallium nitride (GaN) power device in accordance with the present disclosure.

FIG. 7B is a line drawing of a bottom side of a GaN power device having a plurality of circular/cylindrical vias in accordance with the present disclosure.

FIG. 8 is a graphic depicting junction temperature versus power dissipation for a related art power device having a plurality of oval vias such as the one of FIG. 1 in contrast to a power device fabricated onto a substrate having a plurality of vias such as those of FIG. 3.

### DETAILED DESCRIPTION

The embodiments set forth below represent the necessary information to enable those skilled in the art to practice the disclosure and illustrate the best mode of practicing the disclosure. Upon reading the following description in light of the accompanying drawings, those skilled in the art will understand the concepts of the disclosure and will recognize applications of these concepts not particularly addressed herein. It should be understood that these concepts and applications fall within the scope of the disclosure and the accompanying claims.

It will be understood that when an element such as a layer, region, or substrate is referred to as being “over,” “on,” “disposed on,” “in,” or extending “onto” another element, it can be directly over, directly on, directly disposed on, directly in, or extend directly onto the other element or intervening elements may also be present. In contrast, when an element is referred to as being “directly over,” “directly on,” “directly disposed on,” “directly in,” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

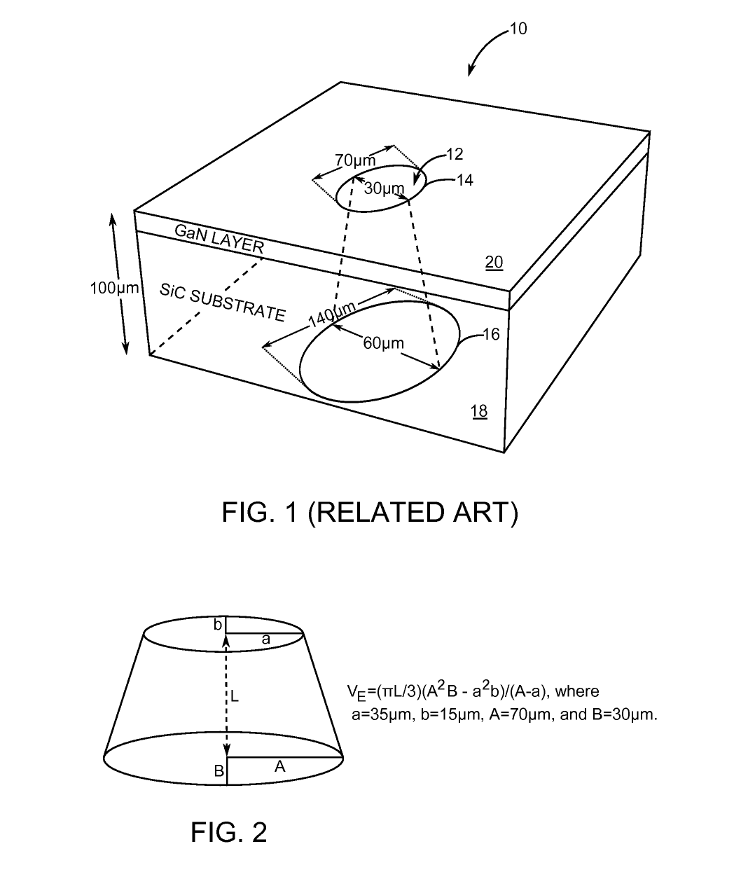

FIG. 1 is a depiction of a related art semiconductor die 10 having an oval via 12 that has a relatively large and undesirable air cavity that includes a cross section outlined in dashed lines that extend from a topside aperture 14 to a bottom side aperture 16. The relatively large air cavity results in poor thermal performance for the related art semiconductor die 10. The reason for the poor performance is at least two-fold. First, air within the air cavity is a very poor conductor of heat. Secondly, a relatively large amount of a substrate 18 that is a very good conductor of heat has been removed to form the oval via 12, due to a long etch time needed to etch through the substrate 18, which in this case is made of a nearly 100 μm thick silicon carbide (SiC) wafer. The long etch time results in the bottom side aperture 16 being around about twice the size of the topside aperture 14. In this exemplary case, the topside aperture 14 emerges from a gallium nitride GaN layer 20 with an oval that has a minor axis length of 30 μm and a major axis length of 70 μm, and the bottom side aperture 16 finishes the long etch time with a minor axis length of 60 μm and a major axis length of 140 μm. As a result, an undesirable open space volume is left within the dimensions of the oval via 12. The undesirable open space volume forms the air cavity mentioned above.

FIG. 2 is a diagram of an elliptical frustum and an associated equation for a volume V_{E} that is usable to approximate the open space volume of the oval via 12 depicted in FIG. 1. It is to be understood that the oval via 12 can have aperture shapes that include semicircular ends and straight sides and an axial length. In such a case, the equation for V_{E} is a good approximation as opposed to an exact calculation. Using values a=35 μm, b=15 μm, A=70 μm, and B=30 μm, the volume V_{E} calculated with equation 1 below is 144,320 μm³.

V_{E}(πL/3)(A²B−a²b)/(A−a) (Eq. 1)

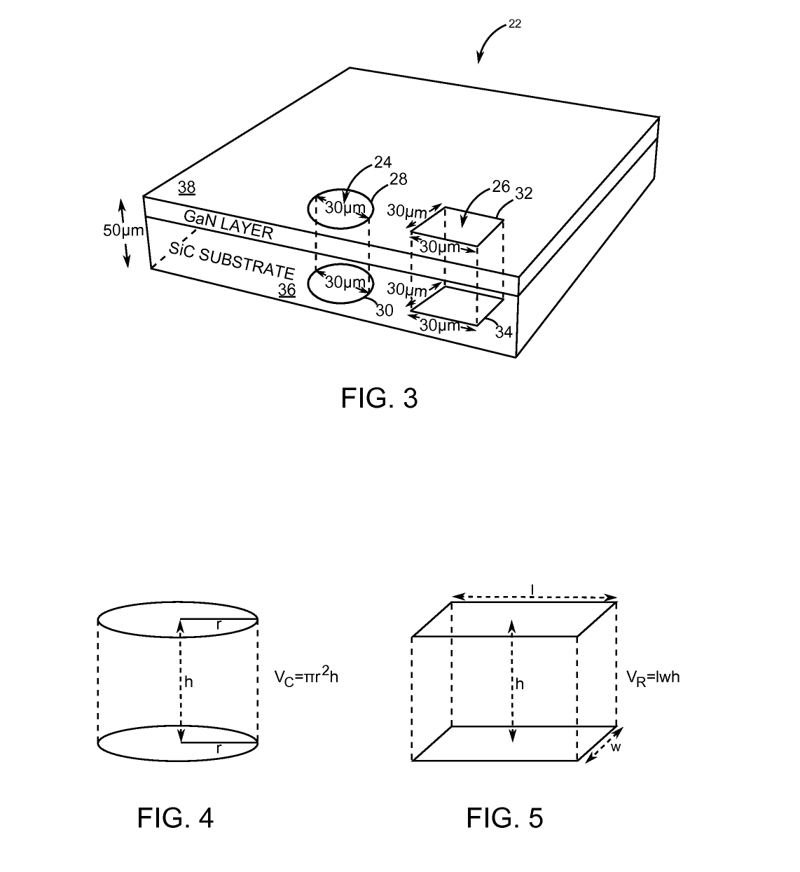

FIG. 3 is a depiction of a semiconductor die 22 having a substantially cylindrical via 24 and a substantially square via 26 that are both in accordance with the present disclosure. The cylindrical via 24 has a topside circular aperture 28 and a bottom side circular aperture 30. A topside square aperture 32 and a bottom side square aperture 34 are associated with the square via 26. In this case, a substrate 36 has a reduced thickness that is around about one-half the thickness of the substrate 18 of FIG. 1. In this case, the semiconductor die 22 is made up of a GaN layer 38 disposed onto the substrate 36. The thickness of the GaN layer 38 combined with the substrate 36 is around 50 μm thick. The reduced thickness of the substrate 36 allows for a relatively faster etch time for fabricating the circular via 24 and the square via 26. As a result of the faster etch time, the topside circular aperture 28 and the bottom side circular aperture 30 are practically the same diameter, which in this exemplary case is 30 μm. As a result, the circular via 24 has an open space that is substantially cylindrical. Moreover, the topside square aperture 32 and the bottom side square aperture 34 have practically the same dimensions as a result of the faster etch time. Thus, the square via 26 has an open space that is substantially box shaped. In both the case of the circular via 24 and the square via 26, an internal open space contained within is very much smaller in volume than for the related art oval via 12 of FIG. 1.

In this regard, FIG. 4 is a diagram of a cylinder and an associated equation for calculating a cylindrical volume V_{C} of the circular via 24 of FIG. 3. In this case, a radius r of the circular via 24 is 15 μm, and since the height h is equal to the 50 μm thickness of the semiconductor die 22, the cylindrical volume V_{C} is 35,342 μm³ as given by the following equation.

V_{C}=πr²h, where r is 15 μm and h=50 μm (Eq. 2)

In further regard, FIG. 5 is a diagram of a box with an associated equation for calculating the box-shaped volume V_{R} of the substantially square via 26 depicted in FIG. 3. In this exemplary case, a length I and a width w are both equal to 30 μm, while the height h remains 50 μm. Accordingly, the box-shaped volume V_{R} is 45,000 μm³ as given by the following equation.

V_{R}=Iwh, where I=w=20 μm and h=50 μm (Eq. 3)

It is to be understood that each of a plurality of vias can be substantially rectangular with rounded corners and an axial length, wherein each rounded corner has a radius of curvature that has a range from around about 10% of the length to around about 25% of the axial length.

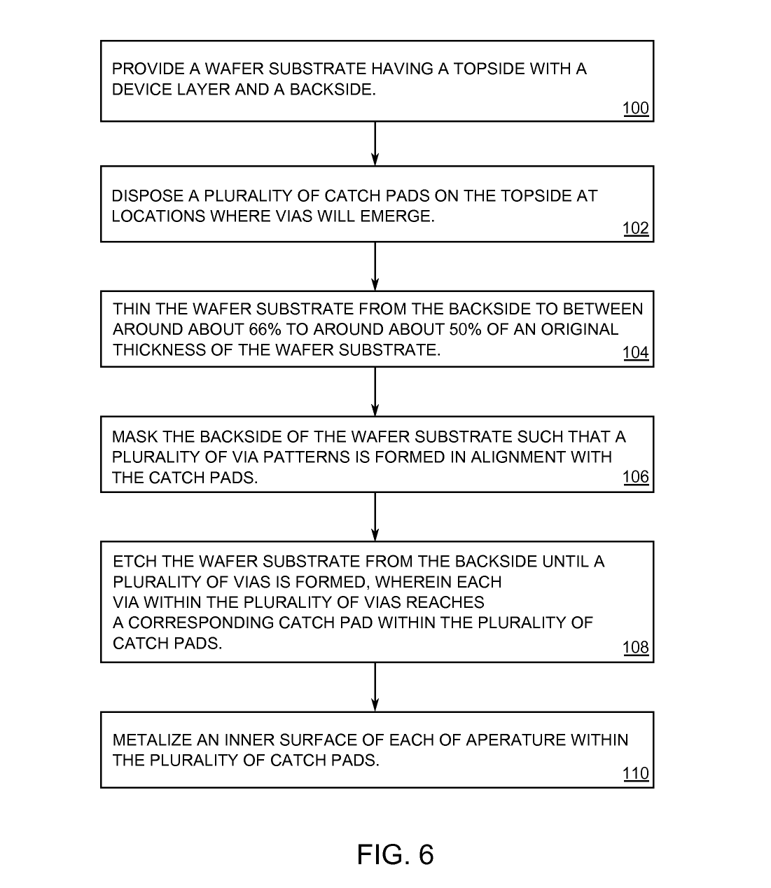

FIG. 6 is a process flow chart for manufacturing the semiconductor die 22 having the vias of FIG. 3 in accordance with the present disclosure. The process begins with providing a wafer substrate having a topside with a device layer and a backside (step 100). Next, a plurality of catch pads is disposed on the topside at locations where the vias will emerge (step 102). Thereafter, the wafer substrate is thinned from the backside to between around about 66% to around about 50% of an original thickness of the original wafer substrate (step 104). It is to be understood that it may be desirable to reverse the order of the step 102 and the step 104 in some instances.

Once the wafer substrate is thinned, the backside of the wafer substrate is masked such that a plurality of via patterns is formed in alignment with the plurality of catch pads (step 106). Next, the wafer substrate is etched from the backside until a plurality of vias is formed, wherein each via within the plurality of vias reaches a corresponding catch pad within the plurality of catch pads (step 108). Lastly, an inner surface of each aperture within the plurality of catch pads is metalized (step 110).

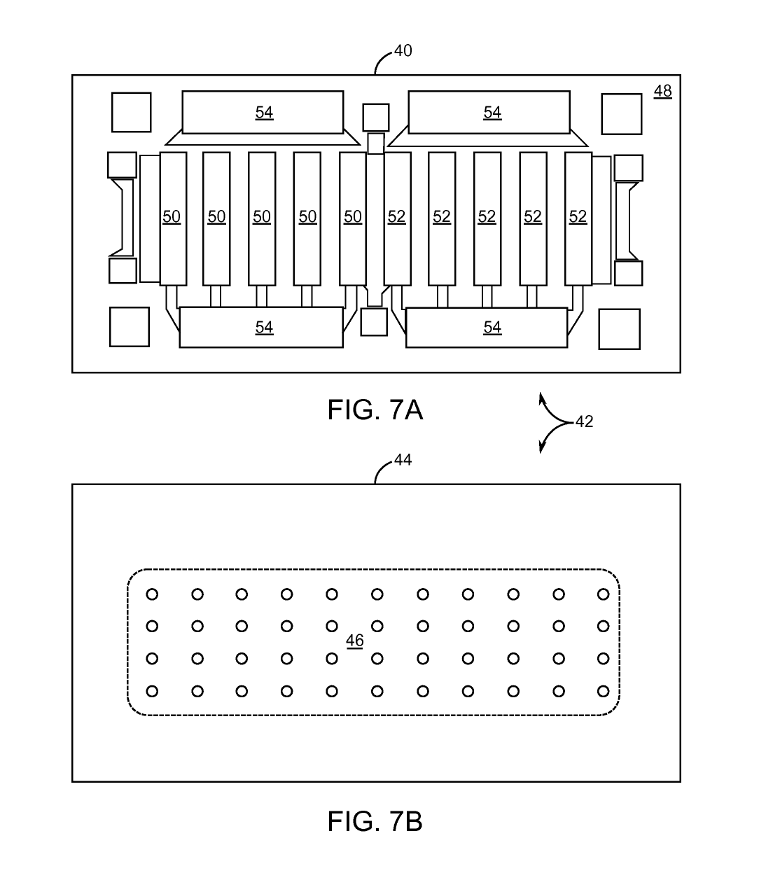

FIG. 7A is a line drawing of a topside 40 of a gallium nitride (GaN) power device 42 and FIG. 7B is a line drawing of a bottom side 44 of the GaN power device 42 having a plurality of circular vias 46 in accordance with the present disclosure. Each of the plurality of circular vias 46 in this exemplary embodiment has a diameter of around about 30 μm. It is to be understood that individual ones of the plurality of vias can have an open space volume of between less than around about 70,000 cubic micrometers to around about 20,000 cubic micrometers depending on the diameter of each the plurality of circular vias 46 and the thickness of a wafer substrate that is thinned.

The GaN power device 42 was fabricated using the process steps provided in FIG. 6. As shown in FIG. 7A, a device layer 48 includes drain fingers 50 and source fingers 52 that couple to bonding pads 54. The plurality of circular vias 46 shown in FIG. 7B provide the GaN power device 42 with much greater thermal performance than is obtainable using a plurality of vias such as the oval via 12 depicted in FIG. 1.

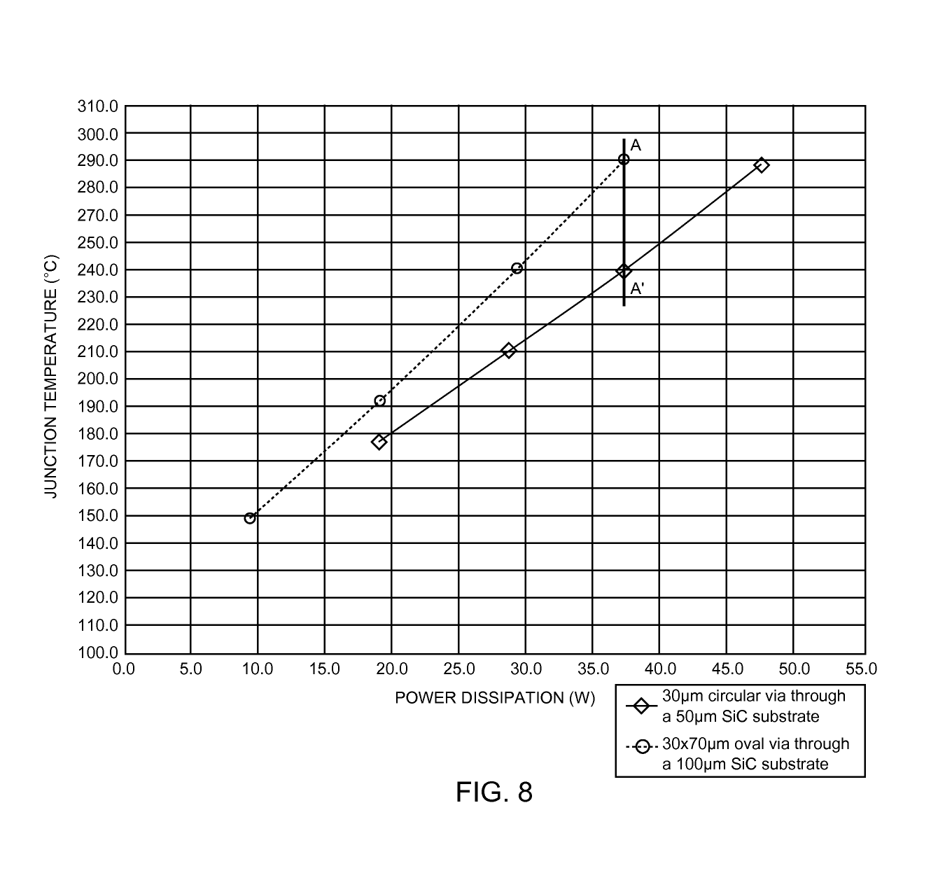

FIG. 8 is a graph depicting junction temperature versus power dissipation for a related art power device having a plurality of oval vias such as the oval via 12 of FIG. 1 in contrast to a power device fabricated onto a substrate having a plurality of vias such as those of FIG. 3. Notice that a difference in junction temperature for test points A and A′ for a power dissipation of 38W is relatively large at a little over 50° C. As power dissipation increases, the junction temperature for GaN devices fabricated in accordance to the present disclosure increases at a much slower rate than traditional GaN devices manufactured using related art methods that result in the large air cavities of the oval via 12 of FIG. 1.

Those skilled in the art will recognize improvements and modifications to the embodiments of the present disclosure. All such improvements and modifications are considered within the scope of the concepts disclosed herein and the claims that follow.

What is claimed is:

1. A semiconductor die having improved thermal performance comprising a substrate having a device layer with a plurality of vias that pass through the substrate and the device layer, wherein individual ones of the plurality of vias have an open space volume of between less than around about 70,000 cubic micrometers and to around about 20,000 cubic micrometers.

2. The semiconductor die of claim 1 wherein each of at least a portion of the plurality of vias are substantially rectangular having a width and a length.

3. The semiconductor die of claim 2 wherein the width and length are both around about 30 micrometers.

4. The semiconductor die of claim 1 wherein each of at least a portion of the plurality of vias are substantially rectangular with rounded corners and an axial length, wherein each rounded corner has a radius of curvature that has a range from around about 10% of the axial length to around about 25% of the axial length.

5. The semiconductor die of claim 1 wherein each of at least a portion of the plurality of vias are substantially cylindrical having a diameter and a length.

6. The semiconductor die of claim 5 wherein the open space volume is less than around about 36,000 cubic micrometers.

7. The semiconductor die of claim 6 wherein the length is around 50 micrometers.

8. The semiconductor die of claim 1 wherein the device layer is made of gallium nitride (GaN).

9. The semiconductor die of claim 1 wherein the substrate is made of silicon carbide (SiC).

10. The semiconductor die of claim 1 wherein the substrate is made of SiC and the device layer is made of GaN.

11. A method of making a semiconductor die having improved thermal performance comprising:
providing a wafer substrate having a front side with a device layer and a backside;
forming a plurality of catch pads on the front side;
thinning the wafer substrate from the backside to between around about 66% to around about 50% of an original thickness of the wafer substrate;
masking the backside of the wafer substrate such that a plurality of via patterns is formed; and
etching the wafer substrate from the backside until a plurality of vias is formed, wherein each aperture within the plurality of vias reaches a corresponding catch pad within the plurality of catch pads.

12. The method of making the semiconductor die of claim 11 further including metalizing an inner surface of each via within the plurality of vias.

13. The method of making the semiconductor die of claim 11 wherein each of at least a portion of the plurality of vias are substantially rectangular having a width and a length.

14. The method of making the semiconductor die of claim 13 wherein the width and length are both around about 30 micrometers.

15. The method of making the semiconductor die of claim 11 wherein each of at least a portion of the plurality of vias are substantially rectangular rounded corners and a length, wherein each rounded corner has a radius of curvature that has a range from around about 10% of the length to around about 25% of the length.

16. The method of making the semiconductor die of claim 11 wherein each of at least a portion of the plurality of vias are substantially cylindrical having a diameter and a length.

17. The method of making the semiconductor die of claim 16 wherein an open space volume of each of the plurality of vias is less than around about 36,000 cubic micrometers.

18. The method of making the semiconductor die of claim 17 wherein the length is around 50 micrometers.

19. The method of making the semiconductor die of claim 11 wherein the device layer is made of gallium nitride (GaN).

20. The method of making the semiconductor die of claim 19 wherein the wafer substrate is made of silicon carbide (SiC).
